(19) United States
(12) Patent Application Publication
(10) Pub. No.: US 2008/0137400 A1
(43) Pub. Date: Jun. 12, 2008

(54) Phase Change Memory Cell with Thermal Barrier and Method for Fabricating the Same

(75) Inventors: Shih Hung Chen, Elmsford, NY (US); Hsiang Lan Lung, Elmsford, NY (US); Yi-Chou Chen, Cupertino, CA (US)

Correspondence Address: MACRONIX;C/O HAYNES BEFFEL & WOLFELD LLP, P. O. BOX 366, HALF MOON BAY, CA, 94019, US

(73) Assignee: Macronix International Co., Ltd., Hsinchu (TW)

(21) Appl. No.: 11/567,361

(22) Filed: Dec. 6, 2006

(51) Int. Cl. G11C 11/00; H01L 21/02

(52) U.S. Cl. 365/163; 438/54; 257/E21.002

(57) ABSTRACT

A memory cell has thermal isolation material between a bottom electrode and a plug contact to confine heat in a memory element during programming and reset operations. In a particular embodiment, the memory element is a chalcogenide, such as GST. An electrically conductive barrier layer deposited over the contact and on sidewalls of a recess formed over the contact electrically couples the bottom electrode to the contact.

### REFERENCE TO RELATED APPLICATION

This application is related to patent application Ser. No. 11/338,284, Filed 24 Jan. 2006, entitled “Isolated Phase Change Memory Cell and Method for Fabricating the Same” (Attorney Docket No. MXIC 1655-2), which is incorporated herein by reference for all purposes.

### PARTIES TO A JOINT RESEARCH AGREEMENT

International Business Machines Corporation, a New York corporation; Macronix International Corporation, Ltd., a Taiwan corporation; and Infineon Technologies A.G., a German corporation, are parties to a Joint Research Agreement.

### BACKGROUND OF THE INVENTION

1. Field of the Invention

The present invention relates to high density memory devices based on phase change based memory materials, including chalcogenide based materials and other materials, and to methods for manufacturing such devices, and most particularly to a phase change memory element with a thermal barrier between a phase change element and an electrode.

2. Description of Related Art

Phase change based memory materials are widely used in nonvolatile random access memory cells. Such materials, such as chalcogenides and similar materials, can be caused to change phase between an amorphous state and a crystalline state by application of electrical current at levels suitable for implementation in integrated circuits. The generally amorphous state is characterized by higher resistivity than the generally crystalline state, which can be readily sensed to indicate data.

The change from the amorphous to the crystalline state is generally a low current operation. The change from crystalline to amorphous, referred to as reset herein, is generally a higher current operation, which includes a short high current density pulse to melt or breakdown the crystalline structure, after which the phase change material cools quickly, quenching the phase change process, allowing at least a portion of the phase change structure to stabilize in the amorphous state. It is desirable to minimize the magnitude of the reset current used to cause transition of phase change material from a crystalline state to amorphous state. The magnitude of the needed reset current can be reduced by reducing the size of the phase change material element in the cell and of the contact area between electrodes and the phase change material, so that higher current densities are achieved with small absolute current values through the phase change material element.

One direction of development has been toward forming small pores in an integrated circuit structure, and using small quantities of programmable resistive material to fill the small pores. Patents illustrating development toward small pores include: Ovshinsky, “Multibit Single Cell Memory Element Having Tapered Contact,” U.S. Pat. No. 5,687,112, issued 11 Nov. 1997; Zahorik et al., “Method of Making Chalogenide [sic] Memory Device,” U.S. Pat. No. 5,789,277, issued 4 Aug. 1998; Doan et al., “Controllable Ovonic Phase-Change Semiconductor Memory Device and Methods of Fabricating the Same,” U.S. Pat. No. 6,150,253, issued 21 Nov. 2000.

Problems have arisen in manufacturing such devices with very small dimensions, and with variations in process that meet tight specifications needed for large-scale memory devices. One problem associated with the small dimensions of phase change cells has arisen because of the thermal conductivity of materials surrounding the active region. In order to cause phase transitions, the temperature of the active region in the phase change material must reach phase transition thresholds. However, heat generated by the current through the material is conducted away by surrounding structures. This conduction of heat away from the active region in the phase change material slows down the heating effect of the current and interferes with the operation to change the phase.

It is desirable therefore to provide a memory cell structure having a reduced current requirement. It is further desirable to provide a manufacturing process and a structure that are compatible with manufacturing of peripheral circuits on the same integrated circuit.

### SUMMARY OF THE INVENTION

A memory cell is made by providing a substrate, depositing a dielectric layer on the substrate, forming a via within the dielectric layer, and depositing a conducting material (“plug”) in the via. The wafer is planarized to form a first surface, and a portion of the conducting material is removed (etched away) to form a recess having an exposed sidewall and a second surface of the conducting material lower than the first surface. An electrically conductive barrier layer is deposited on the second surface and on the exposed sidewall portion, and a thermal isolation material is deposited on the electrically conductive barrier layer. The thermal isolation material and the electrically conductive barrier material are planarized to form an exposed electrically conductive barrier surface. A bottom electrode is formed on the thermal isolation material extending over and electrically contacting the exposed electrically conductive barrier surface. Memory material is formed on the bottom electrode and a top electrode electrically contacting the memory material is formed.

In a particular embodiment, the electrically conductive barrier layer is TiN having a sickness of 1 to 10 nm. In another embodiment, the bottom electrode is not more than about 30 nm thick. In yet another embodiment, the thermal isolation material comprises spin-on glass.

In a particular embodiment, the exposed electrically conductive barrier surface defines a perimeter surrounding the thermal isolation material and the bottom electrode covers the perimeter. In another embodiment, the memory material and the top electrode form a memory core having a sublithographic pillar of memory material.

In some embodiments, depositing a conducting material in the via forms a seam, and etching the conducting material exposes a seam opening. The thermal isolating material covers the seam opening to provide a surface even with the exposed electrically conductive barrier surface.

In another embodiment, a memory cell is manufactured by providing a substrate, depositing a dielectric layer on the substrate, forming a via within the dielectric layer; depositing a conducting material in the via, and planarizing the dielectric layer and conducting material to form a first surface. The conducting material is etched to form a recess having an exposed sidewall portion and a second surface of the conducting material lower than the first surface. An electrically conductive barrier layer is deposited on the second surface and on the exposed sidewall portion, and a thermal isolation material is deposited on the electrically conductive barrier layer. The thermal isolation material and the electrically conductive barrier material are planarized to form an exposed electrically conductive barrier surface, and a bottom electrode layer is formed on the thermal isolation material and the exposed electrically conductive barrier surface. A memory core is formed on the bottom electrode layer. The memory core has a top electrode and a sublithographic pillar of memory material between the top electrode and the bottom electrode layer. A sidewall spacer is formed around the memory core on the bottom electrode layer; and a bottom electrode is formed according to the sidewall spacer. The bottom electrode contacts at least a portion of the exposed electrically conductive barrier surface to electrically couple the sublithographic pillar of memory material to the conducting material.

In a particular embodiment, the exposed electrically conductive barrier surface forms a circular perimeter having a first diameter, and the sidewall spacer has a second diameter greater than the first diameter. In another embodiment, the lower electrode covers the circular perimeter.

In another embodiment, a memory cell has a substrate, a dielectric layer with a first surface disposed on the substrate, a via within the dielectric layer extending from the first surface, the via having an upper portion surrounded by a sidewall portion and a lower portion, a contact thin the lower portion of the via and having a second surface, an electrically conductive barrier layer overlying and electrically contacting the contact and extending along the sidewall portion to the first surface so as to form an electrically conductive barrier surface at the first surface, the electrically conductive barrier layer defining an interior. A thermal isolation material is within the interior of the electrically conductive barrier layer. A bottom electrode is disposed on and extends across the thermal isolation material and the electrically conductive barrier surface to electrically couple the bottom electrode to the contact. A memory material element is on the bottom electrode, and the thermal isolation material provides thermal isolation between the memory material element and the contact. A top electrode is formed over and electrically contacts the memory material element.

In a particular embodiment, the memory material element comprises a sublithographic pillar of memory material. In a further embodiment, a sidewall spacer is formed around the sublithographic pillar of memory material, and the sidewall spacer defining the bottom electrode.

In a particular embodiment, the memory material element comprises chalcogenide, and in a more particular embodiment, the memory material element comprises germanium, antimony, and tellurium.

In a particular, the thermal isolation material comprises spin-on glass. In a particular embodiment, the contact has a first thermal conductivity and the thermal isolation material has a second thermal conductivity less than the first thermal conductivity.

In a particular embodiment, the electrically conductive barrier layer is TiN having a thickness of about 1 to 10 nm. In a particular embodiment, the bottom electrode is not more than 30 nm thick. In a particular embodiment, the electrically conductive barrier surface defines a perimeter and the bottom electrode covers the perimeter

### BRIEF DESCRIPTION OF THE DRAWINGS

FIG. 1 is a block diagram of an integrated circuit device in accordance with the present invention.

FIG. 2 is a partial schematic diagram of a representative memory array as shown in FIG. 1.

FIGS. 3A-3G illustrate steps in a fabrication sequence of a programmable resistive memory cell with a thermal barrier according to an embodiment of the invention.

FIG. 4 illustrates a programmable resistive memory element with a thermal barrier according to another embodiment of the present invention.

FIGS. 5A and 5B illustrate current flow in programmable resistive memory cells with according to embodiments of the invention.

FIGS. 6A-6I illustrate steps in a fabrication sequence of a programmable resistive memory cell with a thermal barrier according to another embodiment of the invention.

### DETAILED DESCRIPTION

The following detailed description is made with reference to the figures. Preferred embodiments are described to illustrate the present invention, not to limit its scope, which is defined by the claims. Those of ordinary skill in the art will recognize a variety of equivalent variations on the description that follows.

With regard to directional descriptions herein, the orientation of the drawings establish their respective frames of reference, with “up,” “down,” “left” and “right” referring to directions shown on the respective drawings. Similarly, “thickness” refers to a vertical dimension and “width” to the horizontal. These directions have no application to orientation of the circuits in operation or otherwise, as will be understood by those in the art.

There follows a description of an integrated circuit and memory array according to an embodiment, an example of a conventional memory cell, and embodiments of phase change elements and memory cells of the present invention, after which the process for fabricating them are discussed.

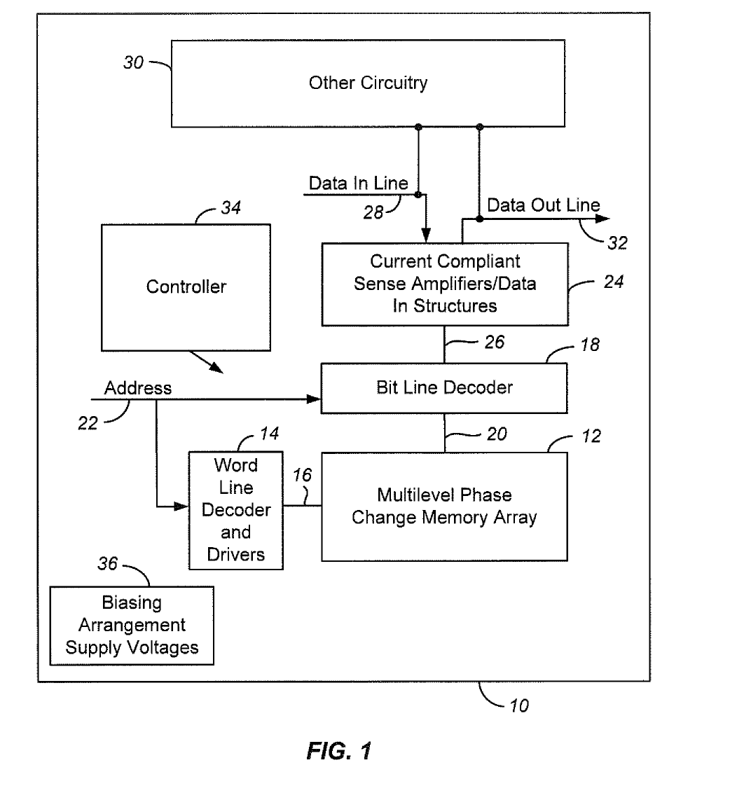

Referring to FIG. 1, shown is a simplified block diagram of an integrated circuit 10 in which the present invention may be implemented. Circuit 10 includes a memory array 12 implemented using phase change memory cells (not shown) including at least one memory cell according to an embodiment of the invention on a semiconductor substrate, discussed more fully below. A word line decoder 14 is in electrical communication with a plurality of word lines 16. A bit line decoder 18 is in electrical communication with a plurality of bit lines 20 to read data from, and write data to, the phase change memory cells (not shown) in array 12. Addresses are supplied on bus 22 to word line decoder and drivers 14 and bit line decoder 18. Sense amplifiers and data-in structures in block 24 are coupled to bit line decoder 18 via data bus 26. Data is supplied via a data-in line 28 from input/output ports on integrated circuit 10, or from other data sources internal or external to integrated circuit 10, to data-in structures in block 24. Other circuitry 30 may be included on integrated circuit 10, such as a general purpose processor or special purpose application circuitry, or a combination of modules providing system-on-a-chip functionality supported by array 12. Data is supplied via a data-out line 32 from the sense amplifiers in block 24 to input/output ports on integrated circuit 10, or to other data destinations internal or external to integrated circuit 10.

A controller 34 implemented in this example, using a bias arrangement state machine, controls the application of bias arrangement supply voltages 36, such as read, program, erase, erase verify and program verify voltages. Controller 34 may be implemented using special-purpose logic circuitry as known in the art. In alternative embodiments, controller 34 comprises a general-purpose processor, which may be implemented on the same integrated circuit to execute a computer program to control the operations of the device. In yet other embodiments, a combination of special-purpose logic circuitry and a general-purpose processor may be utilized for implementation of controller 34.

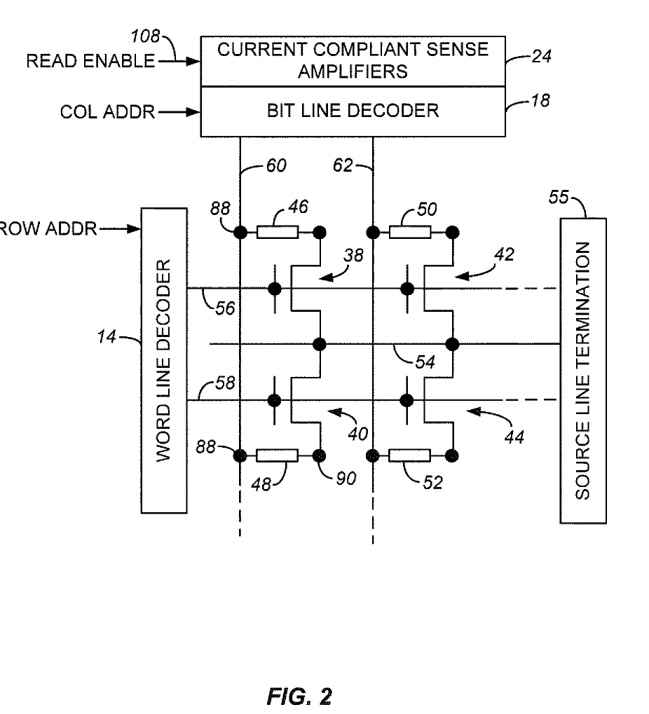

As shown in FIG. 2 each of the memory cells of array 12 includes an access transistor (or other access device such as a diode), four of which are shown as 38, 40, 42 and 44, and a phase change element, shown as 46, 48, 50 and 52. Sources of each of access transistors 38, 40, 42 and 44 are connected in common to a source line 54 that terminates in a source line termination 55. In another embodiment the source lines of the select devices are not electrically connected, but independently controllable. A plurality 16 of word lines including word lines 56 and 58 extend parallel along a first direction. Word lines 56 and 58 are in electrical communication with word line decoder 14. The gates of access transistors 38 and 42 are connected to a common word line, such as word line 56, and the gates of access transistors 40 and 44 are connected in common to word line 58. A plurality 20 of bit lines including bit lines 60 and 62 have one end of phase change elements 46 and 48 connected to bit line 60. Specifically, phase change element 46 is connected between the drain of access transistor 38 and bit line 60, and phase change element 48 is connected between the drain of access transistor 48 and bit line 60. Similarly, phase change element 50 is connected between the drain of access transistor 42 and bit line 62, and phase change element 52 is connected between the drain of access transistor 44 and bit line 62. It should be noted that four memory cells are shown for convenience of discussion and in practice array 12 may comprise thousands to millions of such memory cells. Also, other array structures may be used, e.g. the phase change memory element is connected to source.

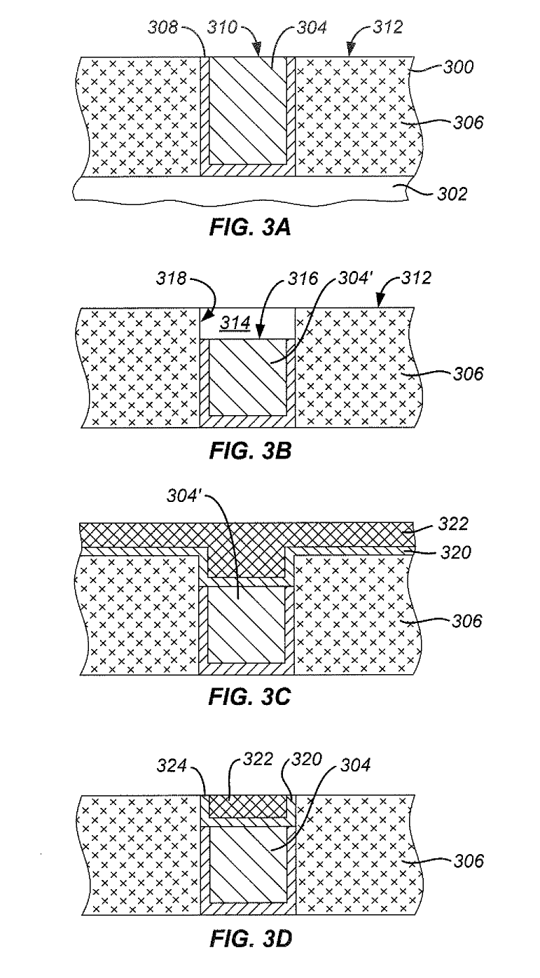

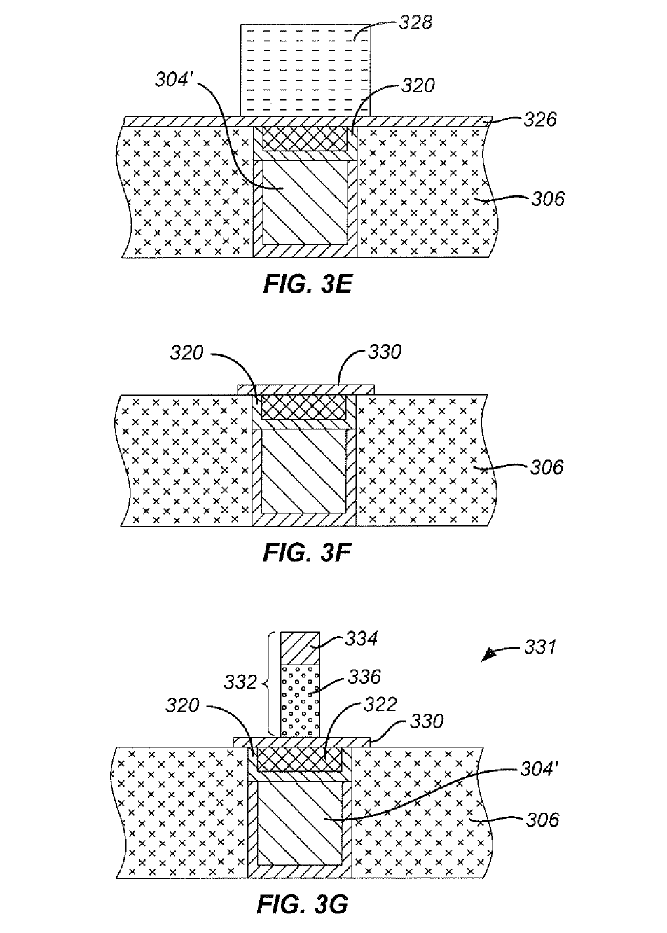

FIGS. 3A-3G illustrate steps in a fabrication sequence of a programmable resistive memory cell with a thermal barrier according to an embodiment of the invention. FIG. 3A shows a memory cell access layer 300 formed on a semiconductor substrate 302. Access layer 300 typically comprises access transistors (not shown). Other types of access devices, such as diodes, may alternatively be used. Access layer 300 includes a plug contact (“contact”) 304, such as a tungsten, polysilicon or TiN plug, extending through a dielectric layer 306. The dielectric layer is silicon dioxide, for example. Other materials are suitable. In one embodiment, the dielectric layer 306 is deposited on the substrate. A via is formed within the dielectric layer, and conductive material is deposited in the via. The conductive material is a plug material, or alternatively a conductive barrier material and a plug material. Plug formation techniques are well known in the art; therefore, a detailed description is omitted. After depositing the conductive material in the

An optional barrier 308 separates the plug 304 from the dielectric layer 306. The barrier 308 provides a diffusion barrier between the plug 304 and the semiconductor substrate 302, and between the plug 304 and the dielectric layer 306, depending on the materials chosen. The barrier 308 is formed from a layer of TaN that is electrically conductive, for example. The plug 304 has an upper surface 310 even with an upper surface 312 of the dielectric layer. A chemical-mechanical polish (“CMP”) technique, for example, is used to form a first surface including the upper surface 310 of the plug and the upper surface 312 of the dielectric layer.

Doped regions in the semiconductor substrate 302 act as terminals of transistors including the word lines and gates for coupling the plug 304 to a common source line (not shown). These elements are preferably formed in conventional manner, and a detailed description is therefore omitted.

FIG. 3B shows the access layer after a portion of the plug and barrier (see FIG. 3A, ref. nums. 304, 308) has been removed using a selective etch technique to form a recess 314 and a contact 304′. An upper surface of the contact 304′ is a second surface 316 that is lower than the first surface. The recess 314 has an exposed sidewall portion 318.

FIG. 3C shows the access layer of FIG. 3B after an electrically conductive barrier layer 320 is deposited within the recess (see FIG. 3B, ref. num. 314) on the second surface (see FIG. 3B, ref. num. 316) and on the exposed sidewall portions (see FIG. 3B, ref. num. 318) forming a cup-like interior. In a particular embodiment, a layer of TiN about 5 nm thick is deposited to form the electrically conductive barrier layer. Alternatively, TaN, Ti, Ta or other of electrically conductive materials or combinations of materials are used. Various deposition techniques, such as chemical vapor deposition (“CVD”) and physical vapor deposition (“PVD”) techniques, are used to deposit electrically conductive barrier layers, as are known in the art.

A thermal isolation material 322 is deposited on the electrically conductive barrier layer 320 and in the interior formed by the electrically conductive barrier layer. The thermal isolation material 322 has lower thermal conductivity than the material of the contact 304′. In one embodiment, SiO₂ is used as the thermal isolation material. Alternatively, nitrogen-doped TaSiN, nitrogen-doped TaN, nitrogen-doped TiN, nitrogen-doped SiO₂, AlN, or Al₂O₃ is used for the thermal isolation material. Other dielectric materials, such as low-k dielectric material and spin-on glass (“SOG”) are alternatively used. SOG is particularly desirable because it provides good fill-in performance.

FIG. 3D shows the access layer of FIG. 3C after a planarization technique has been used to planarize the thermal isolation material 322 and electrically conductive barrier layer 320 to form an exposed electrically conductive barrier surface 324. In one embodiment, the via (not shown) that the plug 304 is formed in is essentially cylindrical. The electrically conductive barrier layer forms a cup-like structure with an exposed electrically conductive barrier surface 324 forming an essentially circular electrically conductive perimeter around the thermal isolation material 322. Alternatively, the exposed electrically conductive barrier surface does not form a complete perimeter, or is not circular.

FIG. 3E shows the access layer of FIG. 3D with a thin bottom electrode layer 326 deposited over the access layer, including the exposed electrically conductive barrier surface (see FIG. 3D, ref. num. 324). A thin bottom electrode layer used in conjunction with the thermal isolation material 322 is desirable to reduce heat loss from the memory element (see FIG. 3G, below). In a particular embodiment, the thin bottom electrode layer 326 is a layer of TiN about 20 nm thick. Alternatively, the thin bottom electrode layer is a layer of TiN deposited by CVD or PVD, TaN, Ti, or Ta, or combinations of materials and layers. Photoresist 328 is patterned to mask selected portions of the thin bottom electrode layer in a subsequent etch step that defines bottom electrodes.

FIG. 3F shows the access layer of FIG. 3E after the bottom electrode layer is etched to form a bottom electrode 330. The bottom electrode 330 overlies at least a portion of the electrically conductive barrier layer 320, which electrically couples the bottom electrode 330 to the contact 304′. In a particular embodiment, the electrically conductive barrier layer forms a conductive perimeter contacting the bottom electrode. In other words, the bottom electrode 330 overlies the exposed electrically conductive barrier surface (see FIG. 3D, ref. num. 324), which in a particular embodiment is essentially a circle when viewed from above. Alternatively, the bottom electrode overlies only a portion of the exposed electrically conductive barrier surface.

FIG. 3G illustrates a memory cell 331 having a sublithographic memory core 332 having a top electrode 334 and a sublithographic pillar of memory material 336 formed on the bottom electrode 330. A lithographic mask and etch technique is used in a particular embodiment to form sublithographic pillars.

The lithographic mask typically has a lateral dimension about equal to the minimum lithographic feature size for the lithographic process used. To reduce the lateral dimension of the lithographic mask, a mask trimming procedure is undertaken, the results of which creates a trimmed lithographic mask with a reduced feature size smaller than the nominal minimum lithographic feature sized defined on the mask. In one embodiment, the reduced feature size is about 40 nm. An etching process employed in one embodiment is a dry anisotropic etch using a RIE, utilizing argon, fluorine or oxygen plasma chemistry. An optical emission tool may be used to identify and control the end point of the etch when the upper surface of the dielectric film layer 306 is encountered.

During conventional etching steps, resistive programmable pillars may be undercut, thus weakening the resulting memory element. The resistive programmable material and etching technique may be selected to avoid undercutting, as described in U.S. patent application Ser. No. 11/456,922; Filed: 12 Jul. 2006, entitled Method for Making a Pillar-Type Phase Change Memory Element, by Hsiang-Lan Lung and Chia Hua Ho (Attorney Docket No. MXIC 1707-1), the disclosure of which is hereby incorporated by reference in its entirety for all purposes.

In a particular embodiment, the pillar of memory material 336 is composed of a phase change alloy that is capable of being switched between a first structural state in which the material is in a generally amorphous solid phase, and a second structural state in which the material is in a generally crystalline solid phase in its local order in the active channel region of the cell. Phase change alloys are at least bistable. The term amorphous is used to refer to a relatively less ordered structure, more disordered than a single crystal, which has the detectable characteristics such as higher electrical resistivity than the crystalline phase. The term crystalline is used to refer to a relatively more ordered structure, more ordered than in an amorphous structure, which has detectable characteristics such as lower electrical resistivity than the amorphous phase.

Typically, phase change materials may be electrically switched between different detectable states of local order across the spectrum between completely amorphous and completely crystalline states. Other material characteristics affected by the change between amorphous and crystalline phases include atomic order, free electron density and activation energy. The material may be switched either into different solid phases or into mixtures of two or more solid phases, providing a gray scale between completely amorphous and completely crystalline states. The electrical properties in the material may vary accordingly.

Phase change alloys can be changed from one phase state to another by application of electrical pulses. It has been observed that a shorter, higher amplitude pulse tends to change the phase change material to a generally amorphous state. A longer, lower amplitude pulse tends to change the phase change material to a generally crystalline state. The energy in a shorter, higher amplitude pulse is high enough to allow for bonds of the crystalline structure to be broken and short enough to prevent the atoms from realigning into a crystalline state. Appropriate profiles for pulses can be determined, without undue experimentation, specifically adapted to a particular phase change alloy.

Chalcogenides are suitable memory materials for use in embodiments of the invention. Chalcogenides include any of the four elements oxygen (O), sulfur (S), selenium (Se), and tellurium (Te), forming part of group VI of the periodic table. Chalcogenides comprise compounds of a chalcogen with a more electropositive element or radical. Chalcogenide alloys comprise combinations of chalcogenides with other materials such as transition metals. A chalcogenide alloy usually contains one or more elements from column six of the periodic table of elements, such as germanium (Ge) and tin (Sn). Often, chalcogenide alloys include combinations including one or more of antimony (Sb), gallium (Ga), indium (In), and silver (Ag). Many phase change based memory materials have been described in technical literature, including alloys of: Ga/Sb, In/Sb, In/Se, Sb/Te, Ge/Te, Ge/Sb/Te, In/Sb/Te, Ga/Se/Te, Sn/Sb/Te, In/Sb/Ge, Ag/In/Sb/Te, Ge/Sn/Sb/Te, Ge/Sb/Se/Te and Te/Ge/Sb/S. In the family of Ge/Sb/Te alloys, a wide range of alloy compositions may be workable. The compositions can be characterized as TeₐGe_{b}Sb_{100-(a+b)}. One researcher has described the most useful alloys as having an average concentration of Te in the deposited materials well below 70%, typically below about 60% and ranged in general from as low as about 23% up to about 58% Te and most preferably about 48% to 58% Te. Concentrations of Ge were above about 5% and ranged from a low of about 8% to about 30% average in the material, remaining generally below 50%. Most preferably, concentrations of Ge ranged from about 8% to about 40%. The remainder of the principal constituent elements in this composition was Sb. These percentages are atomic percentages that total 100% of the atoms of the constituent elements. (Ovshinsky '112 patent, cols. 10-11.) Particular alloys evaluated by another researcher include Ge₂Sb₂Te₅, GeSb₂Te₄ and GeSb₄Te₇. (Noboru Yamada, “Potential of Ge—Sb—Te Phase-Change Optical Disks for High-Data-Rate Recording”, SPIE v.3109, pp. 28-37 (1997).) More generally, a transition metal such as chromium (Cr), iron (Fe), nickel (Ni), niobium (Nb), palladium (Pd), platinum (Pt) and mixtures or alloys thereof may be combined with Ge/Sb/Te to form a phase change alloy that has programmable resistive properties. Specific examples of memory materials that may be useful are given in Ovshinsky '112 at columns 11-13, which examples are hereby incorporated by reference. A material useful for implementation of a PCRAM described herein is Ge₂Sb₂Te₅, which is commonly referred to as “GST”.

Other programmable resistive memory materials may be used in other embodiments of the invention, including N₂-doped GST, GeₓSb_{y}, or other material that uses different crystal phase changes to determine resistance; PrₓCa_{y}MnO₃, PrSrMnO, ZrOₓ, or other material that uses an electrical pulse to change the resistance state; TCNQ, PCBM, TCNQ-PCBM, Cu-TCNQ, Ag-TCNQ, C₆₀-TCNQ, TCNQ doped with other metal, or any other polymer material that has bistable or multi-stable resistance state controlled by an electrical pulse.

The pillar of memory material 336 is deposited as a film layer. Above the pillar of memory material 336 lies the top electrode 334, at least covering the upper surface of the phase change layer. The top electrode is formed from a layer of conductive material, such as TiN. It is convenient to refer to pillar of memory material 336 and top electrode 334 jointly as the memory core 332.

The memory core is formed in a cylindrical hole (pore) of dielectric material (not shown) or is formed as a pillar using a directional etch technique, with the dielectric material being deposited to fill-in around the pillar. The dielectric material preferably consists of one or more layers of silicon oxide or a well-known alternative. Representative materials for the dielectric fill layer include materials that are a combination of the elements silicon Si, carbon C, oxygen O, fluorine F, and hydrogen H and provides electrical isolation between memory elements. In some embodiments, the isolation material comprises a thermally insulating material, such as SiO₂, SiCOH, polyimide, polyamide, and fluorocarbon polymers. Generally, a thermally insulating material should have a thermal conductivity less than that of SiO₂, or less than about 0.014 J/cm*degK*sec.

Many low-K materials, where low-K materials have permittivity less that that of SiO₂, are suitable for use in the dielectric fill layer, and include fluorinated SiO₂, silsesquioxane, polyarylene ethers, parylene, fluoro-polymers, fluorinated amorphous carbon, diamond-like carbon, porous silica, mesoporous silica, porous silsesquioxane, porous polyimide, and porous polyarylene ethers. A single layer or combination of layers can provide thermal isolation. Silicon nitride or other materials having higher thermal conductivity than SiO₂ may be used when thermal conductivity is not critical.

In operation, a current path exists between the contact 304′, through the electrically conductive barrier layer 320, bottom electrode 330, and pillar of memory material 336 to the top electrode 334. In a particular embodiment, the top electrode is electrically connected and bit line of a memory array. As current flows though the memory material, joule heating causes the temperature of the memory material to rise, and, as explained above, based on the length and amplitude of the current pulse, the memory element can be placed in a SET or RESET condition.

In a conventional phase change memory device, heat applied to the memory element is lost (conducted) to the contact 304′, which is often a relatively good thermal conductor as well as a relatively large thermal mass. This requires higher current and also heats the surrounding areas. In the memory cell of FIG. 3G, the pillar of memory material 336 lies on the bottom electrode 330, which is a relatively small thermal mass with relatively poor thermal conductivity, due to its thinness. The bottom electrode is thermally isolated from the contact 304′ by the thermal barrier material 322. The dielectric layer 306 typically also has low thermal conductivity relative to the contact. The memory cell 331 requires less current during SET or RESET operations than a similar cell without the thin bottom electrode overlying the thermal isolation material, and generates less heat, thus keeping the surrounding areas cooler.

In order to write to memory cell 331, for example, appropriate enabling signals would be fed to the top electrode 334 and the bottom electrode 330. The amount and duration of current is selected to cause the memory material 336 to be heated and then assume either a higher or lower resistive state after cooling. The memory element is read by passing a low level current pulse though the element and sensing its resistance.

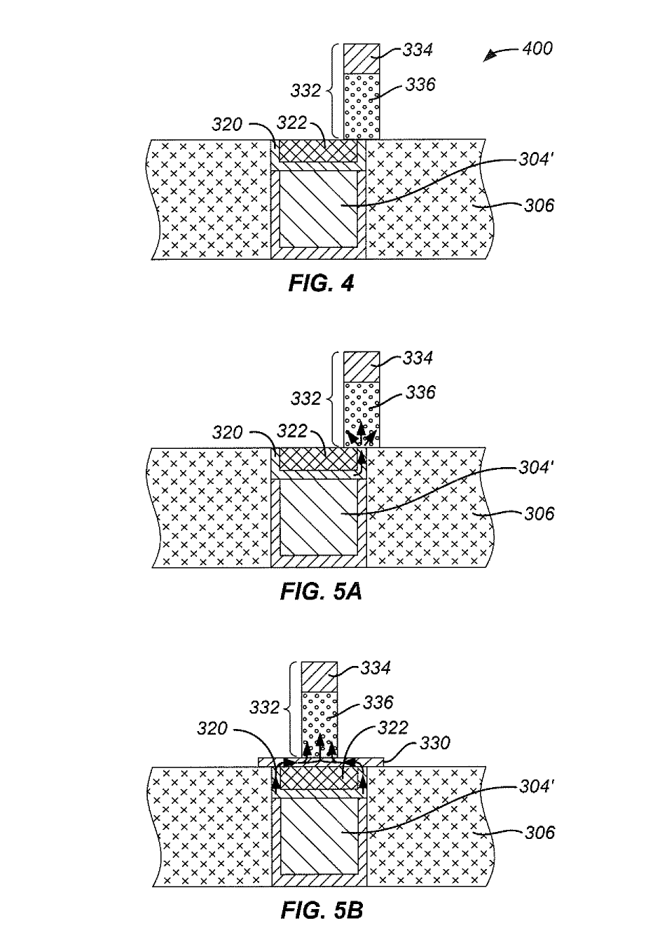

FIG. 4 illustrates a memory cell 400 without a thin bottom electrode. A memory core 332 having a top electrode 334 and a sublithographic pillar of memory material 336 sits on the electrically conductive barrier layer 320, thermal isolation material 322, and dielectric layer 306. Alternatively, the memory core 332 sits on the electrically conductive barrier layer 320 and the thermal isolation material 322, or the electrically conductive barrier layer 320 and the dielectric layer 306. In each case, the pillar of memory material 336 is thermally isolated from the contact 304′, and electrically connected to the contact 304, through the electrically conductive barrier layer 320.

FIGS. 5A and 5B illustrate current flow in programmable resistive memory cells with according to embodiments of the invention. In FIG. 5A, current, represented by arrows 500, is relatively crowded where the pillar of memory material 336 contacts the electrically conductive barrier layer 320. In FIG. 5B, the bottom electrode 330 collects current from the electrically conductive barrier layer and provides the current to the pillar of memory material 336 in a more uniform fashion. This is desirable for more consistent programming conditions for the memory cells in a memory array. While FIG. 5B shows the pillar of memory material 336 essentially centered on the bottom electrode 330, more uniform current would be provided to the pillar of memory material 336 even if it were not centered. The bottom electrode 330 also provides a larger target area to align the memory core to during fabrication. The bottom electrode also provides a smooth, homogeneous interface to the memory material. This improves adhesion of the memory material, which is subject to heating and cooling during operation of the memory cell, to the substrate, thus improving stability and reliability. The memory material 336 in FIG. 5A overlies the thermal isolation material 322, the electrically conductive barrier layer 320, and the dielectric layer 306, which can degrade adhesion of the memory material at that interface.

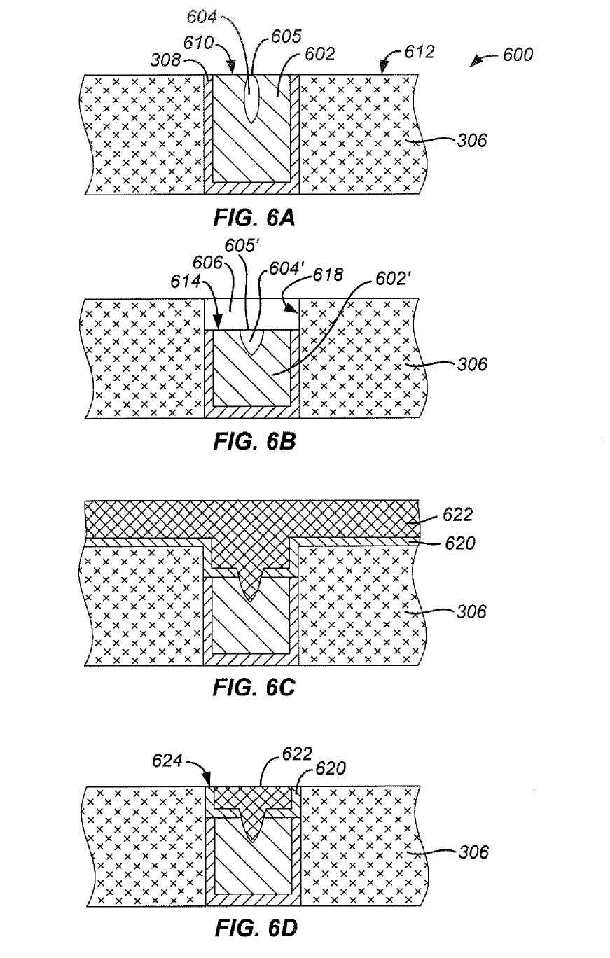

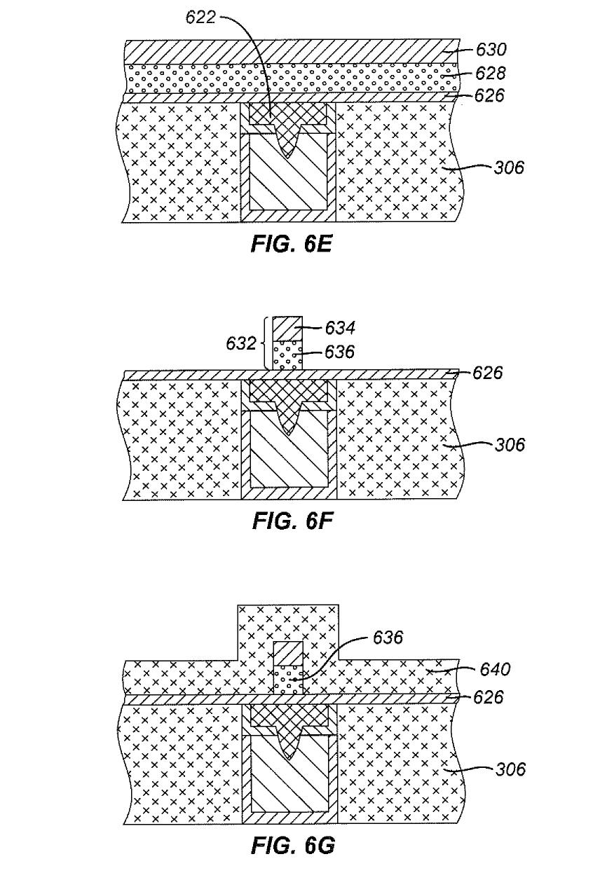

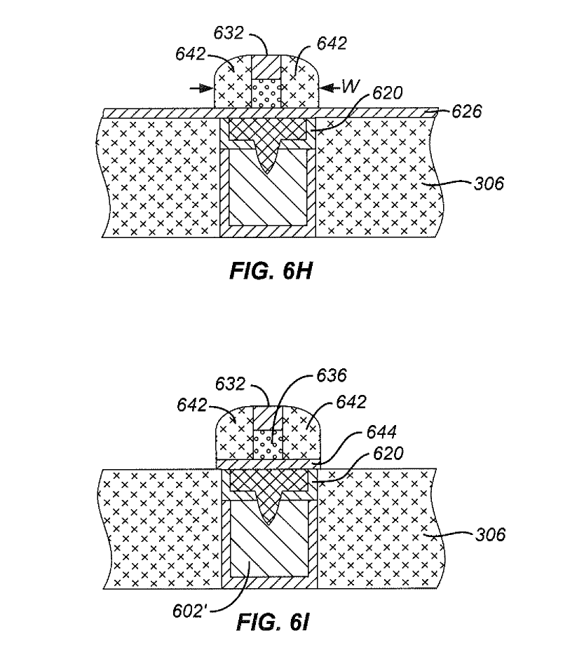

FIGS. 6A-6I illustrate steps in a fabrication sequence of a programmable resistive memory cell with a thermal barrier according to another embodiment of the invention. FIG. 6A shows a memory cell access layer 600 formed on a semiconductor substrate (not shown). Access layer 600 typically comprises access transistors (not shown). Other types of access devices may alternatively be used. Access layer 600 includes a contact 602, such as a tungsten, polysilicon or TiN plug, extending through a dielectric layer 306. The dielectric layer is silicon dioxide, for example. Other materials are suitable. In one embodiment, the dielectric layer 306 is deposited on the substrate. A via is formed within the dielectric layer, and conductive material is deposited in the via. The conductive material is a plug material, or alternatively a conductive barrier material and a plug material. Plug formation techniques are well known in the art; therefore, a detailed description is omitted.

A seam 604 forms during plug formation. The seam 604 is a void that extends into the plug 602 below the first surface. Planarization of the wafer exposes a seam opening 605. The seam 604 and opening 605 cause adhesion and reliability problems.

An optional barrier 308 separates the plug 602 from the dielectric layer 306. The barrier 308 provides a diffusion barrier between the plug 602 and the semiconductor substrate, and between the plug 602 and the dielectric layer 306, depending on the materials chosen. The barrier 308 is formed from a layer of electrically conductive TaN, for example. The plug 602 has an upper surface 610 even with an upper surface 612 of the dielectric layer. A chemical-mechanical polish (“CMP”) technique, for example, is used to form a first surface including the upper surface 610 of the plug and the upper surface 612 of the dielectric layer.

Doped regions in the semiconductor substrate act as terminals of transistors including the word lines and gates for coupling the plug 602 to a common source line (not shown). These elements are preferably formed in conventional manner, and a detailed description is therefore omitted.

FIG. 6B shows the access layer after a portion of the plug and barrier (see FIG. 6A, ref. nums. 602, 308) has been removed using a selective etch technique to form a recess 606 and a contact 602′. An upper surface of the contact 602′ is a second surface 614 that is lower than the first surface (see FIG. 6A, ref. num. 612). The recess has an exposed sidewall portion 618. Removing a portion of the plug also removes an upper portion of the seam, leaving a reduced seam 604′ with a wider seam opening 605′. The wider seam opening facilitates filling the seam with material.

FIG. 6C shows the access layer of FIG. 6B after an electrically conductive barrier layer 620 is deposited on the second surface (see FIG. 6B, ref. num. 614) and on the exposed sidewall portions (see FIG. 6B, ref. num. 618) of the recess (see FIG. 6B, ref. num. 606). In a particular embodiment, a layer of TiN about 5 nm thick is deposited to form the electrically conductive barrier layer. Alternatively, TaN, Ti, Ta or other of electrically conductive materials or combinations of materials are used. Various deposition techniques, such as chemical vapor deposition (“CVD”) and physical vapor deposition (“PVD”) techniques, are used to deposit electrically conductive barrier layers, as are known in the art.

A thermal isolation material 622 is deposited on the electrically conductive barrier layer 620. The thermal isolation material 622 has lower thermal conductivity than the material of the contact 602″. In one embodiment, SiO₂ is used as the thermal isolation material. Alternatively, nitrogen-doped TaSiN, nitrogen-doped TaN, nitrogen-doped TiN, nitrogen-doped SiO₂, AlN, or Al₂O₃ is used for the thermal isolation material. Other dielectric materials, such as low-k dielectric material and spin-on glass (“SOG”) are alternatively used. SOG is particularly desirable because it provides good fill-in performance. The conductive barrier layer 620 and thermal isolation material 622 fill the recess and at least partially fill the remaining portion of the seam (see FIG. 6B, ref. nums. 606, 604′).

FIG. 6D shows the access layer of FIG. 6C after a planarization technique has been used to planarize the thermal isolation material 622 and electrically conductive barrier layer 620 to form an exposed electrically conductive barrier surface 624. The thermal isolation material 622 covers the seam opening (see FIG. 6B, ref. num. 605′) to provide a surface 625 even with the exposed electrically conductive barrier surface 624. Planarizing the thermal isolation material 622 provides a flat, seam-free surface for subsequent processing, which improves performance and reliability.

In one embodiment, the via (not shown) that the plug is formed in is essentially cylindrical. The exposed electrically conductive barrier surface 624 forms an essentially circular electrically conductive perimeter around the thermal isolation material 622. Alternatively, the exposed electrically conductive barrier surface does not form a complete perimeter, or is not circular.

FIG. 6E shows the access layer of FIG. 6D with a thin bottom electrode layer 626 deposited over the access layer, including the exposed electrically conductive barrier surface (see FIG. 6D, ref. num. 624). A thin bottom electrode layer used in conjunction with the thermal isolation material 622 is desirable to reduce heat loss from the memory element (see FIG. 3G, below). In a particular embodiment, the thin bottom electrode layer 326 is a layer of TiN about 20 nm thick, which reduces lateral heat conduction, compared to a thicker layer. Alternatively, the thin bottom electrode layer is a layer of TiN deposited by CVD or PVD, TaN, Ti, or Ta, or combinations of materials and layers.

A layer of memory material 628 is formed over the bottom electrode layer 626, and a top electrode layer 630 is formed over the layer of memory material 628. The top electrode layer is formed from conductive material, such as TiN. The memory material layer 628 is composed of a phase change alloy that is capable of being switched between a first structural state in which the material is in a generally amorphous solid phase, and a second structural state in which the material is in a generally crystalline solid phase in its local order in the active channel region of the cell. Phase change alloys are described in greater detail in reference to FIG. 3G, above. In a particular embodiment, the layer of memory material layer 628 is a chalcogenide, and in a more particular embodiment, is GST. Other materials for the memory material layer are alternatively used. The layer of memory material is preferably about 20 nm to about 120 nm thick, typically about 80 nm thick.

FIG. 6F shows the access layer of FIG. 6E after forming a memory core 632 from the memory material layer and the top electrode layer. The memory core 634 includes a top electrode 334 and a sublithographic pillar of memory material 636 formed on the bottom electrode layer 626. A lithographic mask and etch technique is used in a particular embodiment to form sublithographic pillars. Other types of phase change memory cells are alternatively used.

The lithographic mask typically has a lateral dimension about equal to the minimum lithographic feature size for the lithographic process used. To reduce the lateral dimension of the lithographic mask, a mask trimming procedure is undertaken, the results of which creates a trimmed lithographic mask with a reduced feature size smaller than the nominal minimum lithographic feature sized defined on the mask. In one embodiment, the reduced feature size is about 40 nm. An etching process employed in one embodiment is a dry anisotropic etch using a RIE, utilizing argon, fluorine or oxygen plasma chemistry. An optical emission tool may be used to identify and control the end point of the etch when the upper surface of the dielectric film layer 306 is encountered.

During conventional etching steps, resistive programmable pillars may be undercut, thus weakening the resulting memory element. The resistive programmable material and etching technique may be selected to avoid undercutting, as described in U.S. patent application Ser. No. 11/456,922, Filed 12 Jul. 2006, entitled Method for Making a Pillar-Type Phase Change Memory Element, by Hsiang-Lan Lung and Chia Hua Ho (Attorney Docket No. MXIC 1707-1), the disclosure of which is hereby incorporated by reference in its entirety for all purposes.

FIG. 6G shows the access layer of FIG. 6F with a sidewall-spacer layer 640 formed over the wafer. The sidewall-spacer layer 640 is formed from a material suitable for making sidewall spacers, which are well known in the art. In a particular embodiment, the sidewall spacer layer is a layer of SiO2. Alternatively, SiN is used for the sidewall-spacer layer. In a particular embodiment, the sidewall spacer layer is about 50 nm thick. The thickness of the sidewall-spacer layer 640 is a factor that determines the width of the resultant sidewall spacers (see FIG. 6H, ref. num. 642). In turn, the width of the sidewall spacer determines the size of a self-aligned bottom electrode.

It is generally desirable that the material of the sidewall spacer layer be thermally insulating to retain heat in the pillar of memory material 636 during SET and RESET operations, and provide etch selectivity between the bottom electrode layer 626. In other words, it is generally desirable that the sidewall-spacer layer 640 is capable of being etched to form sidewall spacers without unduly etching the bottom electrode layer 626. Alternatively, the material of the sidewall spacer is removed after forming the self-aligned bottom electrode, and a dielectric fill layer surrounding the memory cores is formed, in which case the sidewall spacer material does not have to be thermally insulating.

FIG. 6H shows the access layer of FIG. 6G after etching the sidewall-spacer layer to form a sidewall spacer 642. In a particular embodiment, the sidewall spacer 642 forms a self-aligned ring around the memory core 632, which is essentially cylindrical. Generally, the sidewall spacer 642 is formed using an anisotropic etch process, which optionally includes one or more isotropic etch techniques. In a particular embodiment, the sidewall spacer 642 provides a feature width W that is greater than the diameter of the cup formed by the electrically conductive barrier layer 620 (i.e., the outer perimeter of the exposed electrically conductive barrier surface). Sidewall spacer formation is well known in the art of semiconductor fabrication, and a more detailed description is therefore omitted.

FIG. 6I shows the access layer of FIG. 6H after etching the bottom electrode layer to form a bottom electrode 644. The bottom electrode 644 is self-aligned to the sidewall spacer 642 and to the memory core 632, and has a width according to the width of the sidewall spacer 642 (see FIG. 6H, ref. num. W). In a particular embodiment, the diameter of the bottom electrode is greater than the diameter of the cup formed by the electrically conductive barrier layer. This allows the bottom electrode to contact the entire diameter of the exposed surface of the electrically conductive barrier layer, which provides good current flow.

Once the memory core 632 has been aligned to the electrically conductive barrier layer 620, the sidewall spacer 642 and bottom electrode 644 self-align to the memory core 632. While FIG. 6I shows the memory core 632 in the center of the cup formed by the electrically conductive barrier layer 620, the embodiment of FIGS. 6A-6I tolerate some mis-alignment. For example, if the memory core is offset from the center of the electrically conductive barrier layer, good memory cell performance is obtained if the bottom electrode contacts a sufficient portion of the exposed surface of the electrically conductive barrier layer to provide a low-resistance path from the contact 602′ to the pillar of memory material 636.

Those in the art will understand that a variety of alternatives and embodiments can be fashioned, all lying within the spirit of the invention disclosed herein. The invention itself however, is defined solely in the claims appended hereto.

What is claimed is:

1. A method for manufacturing a memory cell comprising:
providing a substrate;
depositing a dielectric layer on the substrate;
forming a via within the dielectric layer;
depositing a conducting material in the via;
planarizing the dielectric layer and conducting material to form a first surface;
etching at least the conducting material to form a recess having an exposed sidewall portion and a second surface of the conducting material lower than the first surface;
depositing an electrically conductive barrier layer on the second surface and on the exposed sidewall portion;
depositing a thermal isolation material on the electrically conductive barrier layer;
planarizing the thermal isolation material and the electrically conductive barrier material to form an exposed electrically conductive barrier surface;
forming a bottom electrode on the thermal isolation material extending over and electrically contacting the exposed electrically conductive barrier surface;
forming a memory material on the bottom electrode; and
forming a top electrode electrically contacting the memory material.

2. The method of claim 1 wherein the electrically conductive barrier layer comprises TiN about 1 nm to 10 nm thick.

3. The method of claim 1 wherein the bottom electrode is not more than 30 nm thick.

4. The method of claim 1 wherein the thermal isolation material comprises spin-on glass.

5. The method of claim 1 wherein the exposed electrically conductive barrier surface defines a perimeter surrounding the thermal isolation material and the bottom electrode covers the perimeter.

6. The method of claim 1 wherein the steps of forming a memory material on the bottom electrode and forming a top electrode electrically contacting the memory material comprise a step of forming a memory core having a sublithographic pillar of memory material and the top electrode.

7. The method of claim 1 wherein the step of depositing a conducting material in the via forms a seam, and wherein the step of etching at least the conducting material exposes a seam opening, the thermal isolating material covering the seam opening to provide a surface even with the exposed electrically conductive barrier surface.

8. A method for manufacturing a memory cell comprising:
providing a substrate;
depositing a dielectric layer on the substrate;
forming a via within the dielectric layer;
depositing a conducting material in the via;
planarizing the dielectric layer and conducting material to form a first surface;
etching at least the conducting material to form a recess having an exposed sidewall portion and a second surface of the conducting material lower than the first surface;
depositing an electrically conductive barrier layer on the second surface and on the exposed sidewall portion;
depositing a thermal isolation material on the electrically conductive barrier layer;
planarizing the thermal isolation material and the electrically conductive barrier material to form an exposed electrically conductive barrier surface;
forming a bottom electrode layer on the thermal isolation material and the exposed electrically conductive barrier surface;
forming a memory core on the bottom electrode layer, the memory core having a top electrode and a sublithographic pillar of memory material between the top electrode and the bottom electrode layer;
forming a sidewall spacer around the memory core on the bottom electrode layer; and
forming a bottom electrode from the bottom electrode layer according to the sidewall spacer, the bottom electrode contacting at least a portion of the exposed electrically conductive barrier surface to electrically couple the sublithographic pillar of memory material to the conducting material.

9. The method of claim 8 wherein the exposed electrically conductive barrier surface forms a circular perimeter having a first diameter, and the sidewall spacer has a second diameter greater than the first diameter.

10. The method of claim 9 wherein the lower electrode covers the circular perimeter.

11. A memory cell comprising:
a substrate;
a dielectric layer with a first surface disposed on the substrate;
a via within the dielectric layer extending from the first surface, the via having an upper portion surrounded by a sidewall portion and a lower portion;
a contact within the lower portion of the via and having a second surface;
an electrically conductive barrier layer overlying and electrically contacting the contact and extending along the sidewall portion to the first surface so as to form an electrically conductive barrier surface at the first surface, the electrically conductive barrier layer defining an interior;
thermal isolation material within the interior of the electrically conductive barrier layer;
a bottom electrode disposed on and extending across the thermal isolation material and the electrically conductive barrier surface so the bottom electrode is electrically coupled to the contact;
a memory material element on the bottom electrode, the thermal isolation material providing thermal isolation between the memory material element and the contact; and
a top electrode formed over and electrically contacting the memory material element.

12. The memory cell of claim 11 wherein the memory material element comprises a sublithographic pillar of memory material.

13. The memory cell of claim 12 further comprising a sidewall spacer formed around the sublithographic pillar of memory material, the sidewall spacer defining the bottom electrode.

14. The memory cell of claim 11 wherein the memory material element comprises chalcogenide.

15. The memory cell of claim 11 wherein the memory material element comprises germanium, antimony, and tellurium.

16. The memory cell of claim 11 wherein the thermal isolation material comprises spin-on glass.

17. The memory cell of claim 11 wherein the contact has a first thermal conductivity and the thermal isolation material has a second thermal conductivity less than the first thermal conductivity.

18. The memory cell of claim 11 wherein the wherein the electrically conductive barrier layer comprises TiN about 1 nm to 10 nm thick.

19. The memory cell of claim 11 wherein the bottom electrode is not more than 30 nm thick.

20. The memory cell of claim 11 wherein the electrically conductive barrier surface defines a perimeter and the bottom electrode covers the perimeter.
